(19) United States
(12) Patent Application Publication
(10) Pub. No.: US 2021/0125969 A1
(43) Pub. Date: Apr. 29, 2021

(54) FLEXIBLE LIGHT STRIP

(71) Applicant: LUMILEDS LLC, San Jose, CA (US)

(72) Inventors: Manuel GRAVE, Aachen (DE); Christian KLEIJNEN, Ell (NL); Juergen MERTENS, Wuerselen (DE); Ralph Hubert PETERS, Kerkrade (NL)

(73) Assignee: LUMILEDS LLC, San Jose, CA (US)

(21) Appl. No.: 16/647,332

(22) PCT Filed: Sep. 7, 2018
(86) PCT No.: PCT/EP2018/074114

§ 371 Date: Mar. 13, 2020

(30) Foreign Application Priority Data
Sep. 15, 2017 (EP) 17191284.3

(51) Int. Cl. H01L 25/075; F21S 4/24; H01L 33/62; H01L 23/538; B29C 59/04

(52) U.S. Cl. CPC H01L 25/0753; F21S 4/24; H01L 33/62; B29L 2031/747; B29C 59/04; H01L 2933/0066; H01L 23/5387

(57) ABSTRACT

The invention describes a flexible light strip, an automotive light unit comprising this flexible light strip, an embossing tool and a method to manufacture the light strip, which comprises multiple solid state lighting units as light sources and a flexible carrier for the solid state lighting units attached to the flexible foil, which further comprises a suitable wiring or the carrier is the wiring connecting the solid state lighting units to enable suitable driving of the lighting units to illuminate an environment with the flexible light strip, wherein the carrier comprises multiple buffer areas arranged between adjacent lighting units, where the buffer area extends along a width of the carrier from one edge to the opposite edge of the carrier and being adapted to be able to be compressed and expanded on demand.

### CROSS REFERENCE TO RELATED APPLICATION(S)

This application is a § 371 application of International Application No. PCT/EP2018/074114, filed Sep. 7, 2018, which claims the benefit of EP Patent Application No. 17191284.3, filed Sep. 15, 2017, which are incorporated by reference as if fully set forth.

### FIELD OF INVENTION

The invention relates to a flexible light strip, to an automotive light unit comprising this flexible light strip, an embossing tool and a method to manufacture the light strip.

### BACKGROUND

For automotive lighting application there is a need for styling signaling functions. This can be for rear signaling function like turn lights, position lights or stop lights as well for front signaling function like the position and day running light (DRL). These functions are often provided with styled lines in combination with for example light blades.

A lamp design requires a dedicated source that follows the styling wishes of the car- or set maker. A typical source can be a solid state light source such as a LED source arranged in a line array on a substrate as carrier for the solid state light sources. Typical line arrangements are provided as light strips based on flexible foil technology where surface mounted (SMD) LED packages are attached to the flexible foil. The SMD LED packages can be RBG packages but also a single color LEDs with or without single addressability. LED packages can contain one or more LEDs depending on the required color and function. SMD LED packages are also known as L1 package. The flexible foil is a carrier based typically on copper tracks laminated with a polymer or a flexible plastic substrate screen printed with a silver circuit on for example polyester.

For car lamp design flexibility in the source is a must to meet the design requirements which translates to directionality of the light and following the curvature of the light exit window of the lamp. A lamp design requires a specific design of the flexible foil to meet the styling shapes of the lamp has to be designed for every particular case. A flexible foil provides the possibility to bend in a certain shape which is possible for only one axis perpendicular to the length and parallel to the width of the strip. The width axis of a flexible foil cannot be bended along its because the flexible foil is ridged in this direction. In case of demanding flexible foils comprising a curvature along an axis perpendicular to the carrier foil (bended width), these foils have to be explicitly manufactured as permanently curved foils which prevents any application of these curved foils as linear strips for other applications. Therefore the light strips have to be designed for its particular application limiting the technology to the provided design without having any possibility to reshape the specific design of the same flexible foil in order to adapt the flexible foil to other different applications where other different designs are required. The limitation of the design of the flexible foils to a particular application increases manufacturing costs for the particular light strip.

Therefore there is a demand to provide a light strip allowing bending the light strip also over its width enabling one and the same light strip to be used in different automotive lamps that typically would require a dedicated design of flexible foils for each of the different automotive lamps.

DE 10 2014 215938 A1 discloses an optoelectronic assembly which has a carrier strip and optoelectronic components are provided on the carrier strip. The carrier strip has a first longitudinal section for receiving a first optoelectronic component, at least one second longitudinal section for receiving a second optoelectronic component, and a folding section arranged between the first longitudinal section and the second longitudinal section. The folding section has at least two fold lines. The carrier strip has electrical layers to electrically connect and drive the optoelectronic components.

EP 3 094 161 A1 discloses a lighting device including a laminar support member. The laminar support member has bending lines portioning the support member in a plurality of stripes. The stripes include electrically-powered light radiation sources.

EP 3 136 829 A1 discloses a system for mounting electrical components thereon. The system includes an elongated printed circuit board that is configured to couple a plurality of electronic components. The elongated printed circuit board includes segments with the electronic components on it and other segments in between. The other segments having a smaller width than the width of the segments of the components. The segments with smaller width are bendable.

### SUMMARY

It is an object of the present invention to provide a light strip allowing bending the light strip also over its width enabling one and the same light strip to be used in different lamp designs, especially automotive lamps that typically would require a dedicated design of flexible foils for each of the lamps.

The invention is defined by the independent claims The dependent claims define advantageous embodiments.

According to a first aspect a flexible light strip is provided. The flexible light strip comprises multiple solid state lighting units as light sources and a flexible carrier for the solid state lighting units attached to the flexible carrier, wherein the carrier is a suitable wiring connecting the solid state lighting units to enable suitable driving of the solid state lighting units to illuminate an environment with the flexible light strip, wherein the flexible carrier comprises multiple buffer areas arranged between adjacent solid state lighting units, where the buffer area extends along a width of the flexible carrier from one edge to the opposite edge of the flexible carrier and being adapted to be able to be compressed and expanded on demand.

The flexible light strip might be made of any material providing an electrical insulation for the embedded or coated wiring and a certain flexibility in order to be bended without leading to cracks within the flexible carrier. In an embodiment the flexible carrier is a flexible foil comprising the suitable wiring or the flexible carrier is the wiring itself, preferably established by conductive rails, separated from each other in order to avoid a short between the wiring or conductive rails. The term “foil” denotes a thin sheet of material as a carrier with a thickness thin enough to enable bending of the carrier. The flexible foil is based typically on copper tracks laminated with a polymer or a flexible plastic substrate, e.g. polyester, screen printed with a silver circuit on top of the flexible substrate. Foils might be made for instance of Kapton, a polyimide foil which is resistant to high temperatures, or of Pyralux (polyimide-fluoropolymer-foil). These materials are formable into a certain shape and remain in this formed shape. The conductive rails (or wires) are massive wires, which have to be suitably prepared to be bendable without increasing the risk of shorts between the conductive rails or occurring cracks within the rails. The conductive rails (or wires) might be made of copper or any other suitable conductive material, preferably copper coated with layers of nickel or gold. Suitable diameters of such conductive rails may range from 0.2 mm to 0.7 mm, typically about 0.4 mm.

The term “solid state lighting unit” denotes any lighting source that uses semiconductor light-emitting diodes (LEDs), organic light-emitting diodes (OLED), polymer light-emitting diodes (PLED) or laser diodes to illuminate the environment. The term “solid state” refers commonly to light emitted by solid-state electroluminescence, as opposed to incandescent bulbs (which use thermal radiation) or fluorescent tubes. On the flexible carrier the solid state lighting units are electrically connected in series, parallel or a combination of both. The corresponding wiring is laid out accordingly. In case of a flexible foil as the carrier the wiring might be embedded into the foil or deposited as a coating on top of the foil. Commonly the solid state lighting units are attached to the flexible carrier and connected to the wiring by surface mounting technologies, e.g. so-called SMD LED packages might be used. The solid state lighting units may provide a mixture of red/green/blue light or a single color. The solid state lighting units might be addressable with or without single addressability. The solid state lighting units may comprise one or more solid state light sources depending on the required color and function. For instance SMD LED packages are also known as L1 packages.

The buffer area has to be compressed and expanded on demand in order to enable bending of the light strip around an axis perpendicular to the surface of the light strip (bending along its width). Without such buffer areas the light strip made of a flexible material is only bendable around an axis parallel to the surface of the light strip unduly limiting the shaping options for such light strips. In order to provide the required compressibility and expansibility the material of the flexible carrier as a flexible foil might be elastic material providing the compressibility and expansibility even in a flat geometry of the entire light strip. Alternatively for carriers as flexible foils or conductive rails the buffer area might be shaped three-dimensional to provide a material buffer enabling to compress and expand the buffer area by compressing or expanding the three-dimensional structure of the buffer area. In both cases the buffer area extends along a width of the flexible carrier from one edge to the opposite edge of the flexible carrier not to limit the bendability of the light strip. The three-dimensional shape of the buffer area may comprise sharp or rounded edges providing the buffer function.

The light strip according to the present invention might be used for illumination of the environment in any cases, e.g. room illumination, decorative illumination, street illumination or as signal lamp, where the lamp design requires styled lines of light sources to provide a certain light impression.

The light strip according to the present invention allows bending of the light strip also over its width enabling use of the same light strips in different lamp designs, e.g. in automotive lamps, that typically would require a dedicated design of flexible carriers for each of the lamps. The lighting strip can be used in multiple different applications without modification of the manufacturing steps of the light strip therefore reducing the manufacturing costs per light strip. Additionally former required blades to shape the light emitting area in case of extended emitting areas to a certain impression can be avoided since the bendable light strip already provides the demanded shape of the light emitting area.

In an embodiment each of the solid state lighting units is followed by at least one of the buffer areas along a length of the light strip. A high number of buffer areas increase the flexibility of the light strip along a bending axis perpendicular to the surface of the light strip. In case of a buffer area between each solid state lighting units, the bendability is optimized.

In another embodiment the buffer area is shaped as a buckling area in order to decrease the distance between adjacent solid state lighting units in a non-bended state of the light strip along its length. A buckling area comprises at least one three-dimensional shape, e.g. like a bulge, a bump, a buckle or any other suitable shape. The buckling area can be compressed on one side towards one of the edges of the flexible carrier and can be simultaneously expanded on the other side towards the other edge of the flexible carrier in order to enable bending of the flexible carrier (and therefore the light strip) around an axis perpendicular to the surface of the flexible carrier. The buckling area is advantageous, because this kind of bending mechanism does not provide unduly stress to the wiring embedded in or arranged on top of the flexible carrier and therefore reduces the risk of failing wiring.

In another embodiment a maximum height of the buffer area above an area of the flexible carrier between the buffer areas defines the maximum local bending angle for the light strip relative to a linear shape of the light strip when being non-bended provided by each buffer area. The maximum height is half of the length of the buffer area along the length of the light strip. Longer buffer areas provide a larger bendability. Longer buffer areas result in less space for mounting the solid state light units. When using brighter solid state lighting units, the length of the buffer areas can be increased providing an increased bendability of the light strip. Bright solid state lighting units might be high power LEDs but also MID or LOW power LEDs depending on the application light flux requirements. Also the pitch between neighbored solid state lighting units is relevant for adjusting the possible bending radius. Therefore the use of small solid state lighting units leading to smaller areas between the buffer areas enables a shorter bending radius.

In another embodiment the buffer area is shaped as a gable roof comprising two roof sections sloping in opposite directions and placed such that the highest edges meet to form a roof ridge. The gable roof geometry of the buffer area provides good compressibility and good expansibility combined with a decreased effort during manufacturing. The simple geometry can be manufactured easily, which additionally ensures a good manufacturing yield.

In another embodiment a roof angle at the roof ridge provided by the two roof sections is essentially 90 degree in a non-bended state of the light strip along its length. This will ensure a symmetric bending of the flexible foil since this roof angle is present at the middle of the width of the flexible foil when being bended.

In another embodiment the buffer areas are made of a ductile material providing the advantageous properties for the compressing and expanding function of the buffer areas. A ductile material will remain in the bended status without applying any force to hold the flexible carrier in its desired bended shape. Therefore a ductile material will reduce the handling effort during manufacturing of the lamp equipped with the light strip. In case of the carrier as conductive rails common conductive materials such as copper are ductile materials.

According to a second aspect an automotive light unit is provided. The automotive light unit comprises at least one flexible light strip according to the present invention. For automotive lighting application there is a need for styling signaling functions. Flexible styling is enabled by the light strip according to the present invention without further need to shape the lamp impression by additional components like blades etc. The claimed automotive light unit is able to follow the styling wishes of car and set makers. The automotive lamp unit according to the present invention might be used as tail light, stop light, indicator light, daytime running light but also for general lighting where light strips are used.

According to a third aspect an embossing tool to manufacture a light strip according to the present invention is provided. The embossing tool comprises at least one male sub-tool and at least one female sub-tool each comprising embossing surfaces facing towards within the embossing tool, where the embossing surfaces comprise at least one positive and one corresponding negative shape adapted to a demanded shape of a buffer area of the light strip, which comprises multiple solid state lighting units as light sources, a flexible carrier for the solid state lighting units and suitably shaped buffer areas within the flexible carrier between adjacent solid state lighting units to be able to be compressed and expanded on demand. The embossing tool according to the present invention provides the demanded structure of the buffer area and guaranties a proper alignment of the embossed structure of the buffer area. The flexible pre-carrier might be inserted into the embossing tool manually or automatically to manufacture the final flexible carrier comprising the buffer areas as buckling areas. There could be multiple embossing tools arranged in line to simultaneously emboss multiple buffer areas on the flexible carrier. The embossing tool according to the present invention enables easy manufacturing of the demanded shape of the buffer areas. In particular the embossing tool and the corresponding embossing process according to the present invention can be applied to carriers arranged as flexible foils or arranged as conductive rails or wires.

In an embodiment of the embossing tool, the male and female sub-tools are shaped as rotatable cylindrical wheels with lateral surfaces as the embossing surfaces comprising multiple positive and corresponding negative shapes, where the positive and negative shapes are suitable located onto the cylindrical wheels in order to receive each other during rotating the cylindrical wheels. Here the speed of manufacturing can be increased simultaneously by easy handling of the embossing tool. The rotatable cylinders avoid the need of more than one separate embossing tool as would be the case for fast inline production.

In another embodiment of the embossing tool diameters of the cylindrical wheels are suitably adapted to provide releasing of a received pair of the positive and negative shapes simultaneously to receiving a following pair of the positive and negative shapes in order to continuously feed the flexible carrier through the embossing tool without requiring additional motors to pull or push the flexible carrier through the embossing tool.

According to a third aspect a method to manufacture a light strip according to the present invention comprising multiple solid state lighting units as light sources, a flexible carrier for the solid state lighting units and suitably shaped buffer areas between adjacent solid state lighting units is provided. The method comprises the steps of

Providing a flexible pre-carrier as carrier for the solid state lighting units, wherein the pre-carrier is a wiring suitable to connect the solid state lighting units to enable suitable driving of solid state lighting units when being attached to the carrier, wherein the flexible pre-carrier comprises multiple flat pre-buffer areas along the flexible pre-carrier separated from each other to enable placing of the solid state lighting units in between the pre-buffer areas, which extend along a width of the flexible pre-carrier from one edge to the opposite edge of the flexible pre-carrier;

providing an embossing tool for an embossing process comprising a male sub-tool and a female sub-tool each comprising embossing surfaces facing towards within the embossing tool, where the embossing surfaces comprise at least one positive and one corresponding negative shape adapted to the demanded shape of the buffer area of the light strip;

inserting at least the pre-buffer areas of the flexible pre-carrier into the embossing tool between the embossing surfaces;

transferring the flat pre-buffer area into the demanded shape of the buffer area by the positive and corresponding negative shapes receiving each during the embossing process; and

repeating the previous inserting and transferring steps for the following non-treated pre-buffer areas of the flexible pre-carrier until all demanded buffer areas are shaped by the embossing process to be able to be compressed and expanded on demand.

The flexible pre-carrier and the pre-buffer area denote the flexible carrier and the buffer areas before shaping the buffer areas by embossing. In particular the method according to the present invention can be applied to carriers arranged as flexible foils or arranged as conductive rails or wires.

In an embodiment the method further comprises the step of attaching the solid state lighting units to the embossed flexible carrier in order to provide the light strip equipped for illuminating the environment. The mounting (attaching) of the solid state lighting units after the embossing process prevents any damage of the solid state lighting units by the embossing process. In case of damages to the flexible carrier during embossing the damaged carrier can be selected out without wasting attached solid state lighting units.

In another embodiment of the method the flexible pre-carrier already carries one or more solid state lighting units between adjacent pre-buffer areas of the flexible pre-carrier before inserting the pre-buffer areas into the embossing tool, where the embossing surface of the male or female sub-tool comprises a recess suitable to receive the attached solid state lighting unit during embossing the pre-buffer areas in order to provide the light strip for illuminating the environment. Mounting (attaching) of solid state lighting units is easier in case of a flat flexible carrier as being present before executing the embossing process.

In another embodiment of the method the male and female sub-tools are shaped as cylindrical wheels with lateral surfaces as the embossing surfaces comprising multiple positive and corresponding negative shapes suitable located onto the embossing surfaces in order to receive each other during rotating the cylindrical wheels, where the inserting and transferring steps are executed by simultaneously rotating the cylindrical wheels with the flexible pre-carrier inserted between the cylindrical wheels. This embodiment allows for an even faster and easier embossing process.

It shall be understood that a preferred embodiment of the invention can also be any combination of the dependent claims with the respective independent claim.

Further advantageous embodiments are defined below.

### BRIEF DESCRIPTION OF THE DRAWING(S)

These and other aspects of the invention will be apparent from and elucidated with reference to the embodiments described hereinafter.

The invention will now be described, by way of example, based on embodiments with reference to the accompanying drawings.

In the drawings:

FIG. 1 shows a principle sketch of a flexible light strip according to the present invention (a) in a side view, (b) in a top view in a non-bended status with a flexible foil as the carrier, and (c) in a top view in a non-bended status with a wiring as the carrier.

FIG. 2 shows a principle sketch of a flexible light strip according to the present invention (a) in a top view and (b) in a side view in a bended status with bending angle LBA.

FIG. 3 shows a principle sketch of an embodiment of an automotive light unit comprising a light strip according to the present invention.

FIG. 4 shows a principle sketch of an embodiment of an embossing tool to manufacture a light strip according to the present invention.

FIG. 5 shows a principle sketch of another embodiment of an embossing tool to manufacture a light strip according to the present invention.

FIG. 6 shows a principle sketch of an embodiment of the method according to the present invention.

In the Figures, like numbers refer to like objects throughout. Objects in the Figs. are not necessarily drawn to scale.

### DETAILED DESCRIPTION OF THE PREFERRED EMBODIMENT(S)

Various embodiments of the invention will now be described by means of the Figures.

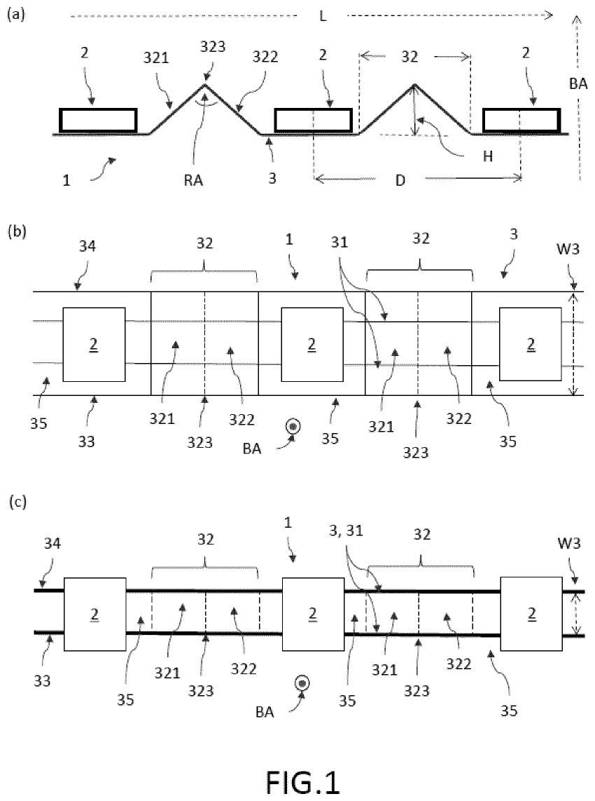

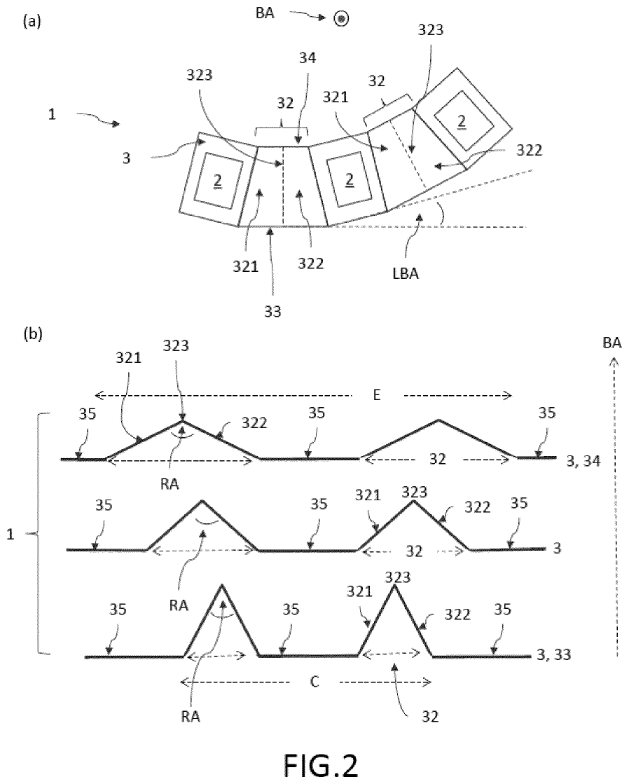

FIG. 1 shows a principle sketch of a flexible light strip 1 according to the present invention (a) in a side view, (b) in a top view in a non-bended status with a flexible foil 3 as the carrier 3, and (c) in a top view in a non-bended status with a wiring 31 as the carrier 3. The light strip 1 comprises multiple solid state lighting units 2 as light sources and a flexible carrier 3 for the solid state lighting units 2 attached to the flexible carrier 3. The light strip may have a length between a few centimeters up to several meters. For ease of understanding only a part of the light strip is shown here. It further comprises a suitable wiring 31 (see part (b)) connecting the solid state lighting units 2 to enable suitable driving of the solid state lighting units 2 to illuminate an environment with the flexible light strip 1. The flexible carrier 3 comprises multiple buffer areas 32 arranged between adjacent solid state lighting units 2 where each of the solid state lighting units 2 is followed by one buffer areas 32 along a length L of the light strip 1. The buffer areas 32 are shaped as a buckling area, here as a gable roof shape, in order to decrease the distance D between adjacent solid state lighting units 2 in a non-bended state of the light strip 1 along its length L. The gable roof shape of the buffer area 32 comprises two roof sections 321, 322 sloping in opposite directions and placed such that the highest edges meet to form a roof ridge 323. This gable roof shape is able to be expanded or compressed (see FIG. 2 for more details) The maximum height H of the buffer area 32 above the area 35 of the flexible carrier 3 between the buffer areas 32 defines the maximum local bending angle LBA for the light strip 1 relative to a linear shape of the light strip 1 when being non-bended provided by each buffer area 32. In this embodiment the roof angle RA at the roof ridge 323 provided by the two roof sections 321, 322 is essentially 90 degree in a non-bended state of the light strip 1 along its length L. The buffer areas 32 might be made of a ductile material. The buffer area 32 extends along a width W3 of the flexible carrier 3 from one edge 33 to the opposite edge 34 of the flexible carrier 3 in order to be bended along a bending axis BA perpendicular to the surface of the flexible foil. In FIG. 1b the carrier is a flexible foil 3 where the edges 33, 34 are the edges of the flexible foil 3. In FIG. 1c the carrier is established by the wiring 31 connecting the solid state lighting units 2, here established by conductive rails 31, where one rail 31 defines one edge 33 of the carrier 3 and the other rail 31 defines the other edge 34 of the carrier 3. Nevertheless both embodiments have the same side view as shown in FIG. 1a. The conductive rails may have any cross section shape suitable for the particular application. The rails (or wires) 31 may have diameters of 0.2 to 0.7 mm, typically of 0.4 mm. The rails 31 (or wires) may be made of copper, preferably coated with layers of nickel or gold.

FIG. 2 shows a principle sketch of a flexible light strip 1 according to the present invention (a) in a top view and (b) in a side view in a bended status with bending angle LBA. For ease of understanding, the embodiment shown in FIG. 2 shows a flexible foil 3 as the carrier 3. However the following also applies to the embodiments using conductive rails or (wires) as the carrier according to FIG. 1c without applying flexible foils. The maximum height H of the buffer area 32 above the area 35 of the flexible foil 3 between the buffer areas 32 defines the maximum local bending angle LBA for the light strip 1 relative to a linear shape of the light strip 1 when being non-bended provided by each buffer area 32. The local bending angle LBA is defined by the extended lines of the edge 33 of the flexible foil 3 extending from the buffer area 32 and from the area 35 between the buffer areas 32. The compressed side 33 of the buffer area 32 is the side facing towards the edge 33 of the flexible foil 3. The expanded side 34 of the buffer area 32 is the side facing towards the opposite edge 34 of the flexible foil 3. The compressed side 33 comprises gable roof shapes with roof sections 321, 322 having a steeper slope compared to the non-bended status. Correspondingly the height of the roof ridge 323 is larger and the roof angle RA is smaller compared to the non-bended status, as shown in FIG. 2b. The middle section of the bended buffer areas 32 remain at a gable roof shape with roof angel RA of approximately 90 degrees and the height H of the non-bended status. The expanded side 34 comprises gable roof shapes with roof sections 321, 322 having a less steep slope compared to the non-bended status. Correspondingly the height of the roof ridge 323 is smaller and the roof angle RA is larger compared to the non-bended status. Correspondingly the roof ridge 323 has a slope increasing from the expanded edge 34 to the compressed edge 33 of the flexible foil resulting in a bended flexible foil 3 (light strip 1) along the length of the flexible foil 3 (light strip 1). The maximum local bending angle LBA is achieved with a roof angle RA of 180 degrees at the expanded side 34 and with a roof angle of 0 degree at the compressed side 33.

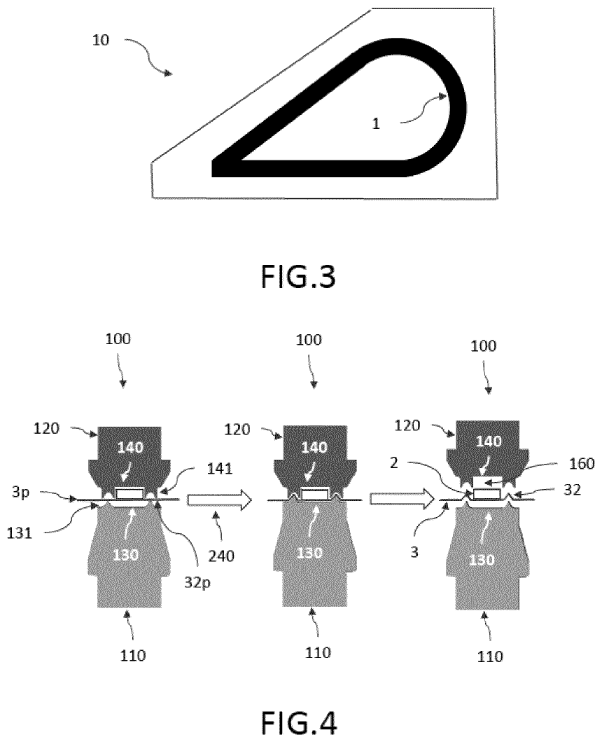

FIG. 3 shows a principle sketch of an embodiment of an automotive light unit 10 comprising a light strip 1 according to the present invention. The light strip 1 is bended by more than 180 degrees over its entire length L in order to provide this particular design of the automotive light unit 100. The same initial light strip 1 might be bended differently in case of demanding differently shaped automotive light units 10. Therefore only one light strip 1 has to be manufactured for providing differently shaped automotive light units 10. The same holds also for light units applied for other purposes than automotive lighting when being equipped with a light strip 1 according to the present invention.

FIG. 4 shows a principle sketch of an embodiment of an embossing tool 100 to manufacture a light strip 1 according to the present invention. The embossing tool 100 comprises a male sub-tool 110 and a female sub-tool 120 each comprising embossing surfaces 130, 140 facing towards within the embossing tool 100, where the embossing surfaces 130, 140 comprise at least one positive shape 131 (male sub-tool) and one corresponding negative shape 141 (female sub-tool) adapted to a demanded shape of a buffer area 32 of the light strip 1, which comprises multiple solid state lighting units 2 as light sources, a flexible carrier 3 for the solid state lighting units 2 and suitably shaped buffer areas 32 within the flexible carrier 3 between adjacent solid state lighting units 2 to be able to be compressed C and expanded E on demand. Here the embossing process executed by the embossing tool 100 is schematically shown by the embossing tool 100 at three different stages of the embossing process. The process step shown in the left is during inserting the flexible pre-carrier 3p with a non-shaped buffer area 32p into the embossing tool 100, where male and female sub-tools 110, 120 are still separated from each other but just fixing the flexible pre-carrier 3p between the positive and negative shapes 131, 141. The step in the middle shows the embossing, where the shape of the pre-buffer area 32p is transferred 240 into the gable roof shape of the buffer area 32. The right step shows the male and female sub-tools 110, 120 and the positive and negative shapes 131, 141 being separated from each other in order to release the finished flexible carrier 3 with attached solid state lighting units 2 as light strip 1 from the embossing tool 100. Here the embossing surface 140 of the female sub-tool 120 comprises a recess 160 to receive the attached solid state lighting units 2 during embossing the pre-buffer areas 32p in order not to damage the solid state lighting units 2 during embossing.

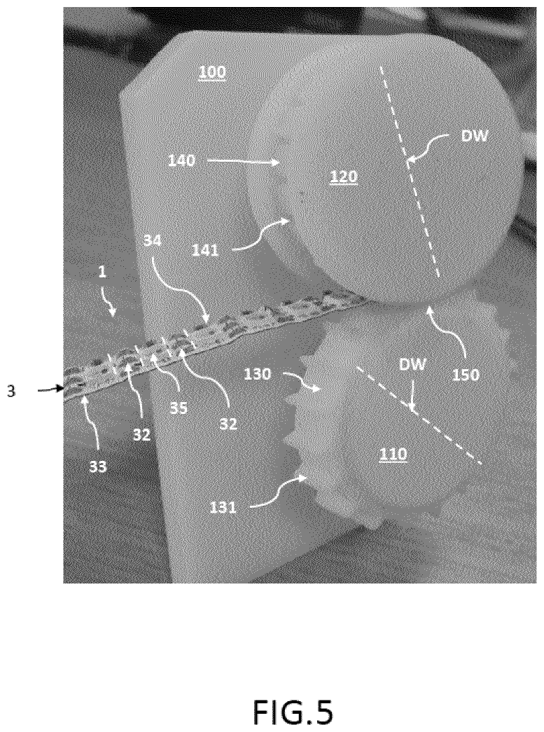

FIG. 5 shows a principle sketch of another embodiment of an embossing tool 100 to manufacture a light strip 1 according to the present invention. In this embodiment the male and female sub-tools 110, 120 are shaped as rotatable cylindrical wheels 110, 120 with lateral surfaces as the embossing surfaces 130, 140 comprising multiple positive and corresponding negative shapes 131, 141, where the positive and negative shapes 131, 141 are suitable located onto the cylindrical wheels 110, 120 in order to receive each other during rotating the cylindrical wheels 110, 120. Here the diameters DW of the cylindrical wheels 110, 120 are suitably adapted to provide releasing of a received pair 150 of the positive and negative shapes 131, 141 simultaneously to receiving a following pair 150 of the positive and negative shapes 131, 141 in order to continuously feed the flexible carrier 3 through the embossing tool 100. In this case the total diameter of the female wheel 120 is larger than the diameter of the male wheel 110, because the female wheel 120 comprises a rim at the edges of the embossing surface 140 covering the positive shapes 131 of the male wheel 110 protruding from the embossing surface 130 of the male wheel 110.

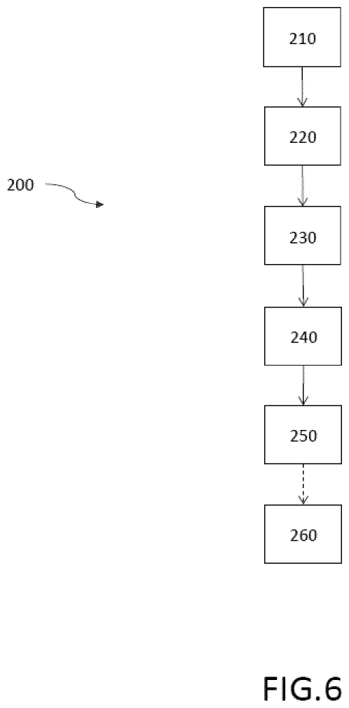

FIG. 6 shows a principle sketch of an embodiment of the method 200 to manufacture a light strip 1 according to the present inventions as shown in FIGS. 1 and 2 in more details. The method 200 comprises the steps of providing 210 a flexible pre-carrier 3p as carrier for the solid state lighting units 2 comprising a wiring 31 suitable to connect the solid state lighting units 2 to enable suitable driving of solid state lighting units 2 when being attached to the carrier 3, wherein the flexible pre-carrier may comprises the solid state lighting units mounted onto the flexible pre-carrier or may be provided without solid state lighting units for later mounting, wherein the flexible pre-carrier 3p comprises multiple flat pre-buffer areas 32p along the flexible pre-carrier 3p separated from each other to enable placing of the solid state lighting units 2 in between the pre-buffer areas 32p, which extend along a width W3 of the flexible pre-carrier 3p from one edge 33 to the opposite edge 34 of the flexible pre-carrier 3p and providing 220 an embossing tool 100 (see FIGS. 4 and 5 for more details) for an embossing process comprising a male sub-tool 110 and a female sub-tool 120 each comprising embossing surfaces 130, 140 facing towards within the embossing tool 100, where the embossing surfaces 130, 140 comprise at least one positive and one corresponding negative shape 131, 141 adapted to the demanded shape of the buffer area 32 of the light strip 1 followed by inserting 230 at least the pre-buffer areas 32p of the flexible pre-carrier 3p into the embossing tool 100 between the embossing surfaces 130, 140, transferring 240 the flat pre-buffer area 32p into the demanded shape of the buffer area 32 by the positive and corresponding negative shapes 131, 141 receiving each during the embossing process, and repeating 250 the previous inserting and transferring steps 230, 240 for the following non-treated pre-buffer areas 32p of the flexible pre-carrier 3p until all demanded buffer areas 32 are shaped by the embossing process to be able to be compressed C and expanded E on demand. In case of the flexible pre-foil does not comprise the solid state lighting units the method further comprises the step of attaching 260 the solid state lighting units 2 to the embossed flexible carrier 3 in order to provide the light strip 1 equipped for illuminating the environment. In case of the flexible pre-carrier 3p already carries one or more solid state lighting units 2 between adjacent pre-buffer areas 32p of the flexible pre-carrier 3p before inserting 230 the pre-buffer areas 32p into the embossing tool 100 the embossing surface 130, 140 of the male or female sub-tool 110, 120 comprises a recess 160 suitable to receive the attached solid state lighting unit 2 during embossing the pre-buffer areas 32p in order not to damage the solid state lighting units during embossing.

In a further embodiment of the method the male and female sub-tools 110, 120 are shaped as cylindrical wheels 110, 120 with lateral surfaces as the embossing surfaces 130, 140 comprising multiple positive and corresponding negative shapes 131, 141 suitable located onto the embossing surfaces 130, 140 in order to receive each other during rotating the cylindrical wheels 110, 120, where the inserting and transferring steps 230, 240 are executed by simultaneously rotating the cylindrical wheels 110, 120 with the flexible pre-carrier 3p inserted between the cylindrical wheels 110, 120.

While the invention has been illustrated and described in detail in the drawings and the foregoing description, such illustration and description are to be considered illustrative or exemplary and not restrictive.

From reading the present disclosure, other modifications will be apparent to persons skilled in the art. Such modifications may involve other features which are already known in the art and which may be used instead of or in addition to features already described herein.

Variations to the disclosed embodiments can be understood and effected by those skilled in the art, from a study of the drawings, the disclosure and the appended claims. In the claims, the word “comprising” does not exclude other elements or steps, and the indefinite article “a” or “an” does not exclude a plurality of elements or steps. The mere fact that certain measures are recited in mutually different dependent claims does not indicate that a combination of these measures cannot be used to advantage.

Any reference signs in the claims should not be construed as limiting the scope thereof.

### LIST OF REFERENCE NUMERALS

1 flexible light strip according to the present invention
2 solid state lighting unit(s), e.g. LED(s)
3 flexible carrier (e.g. flexible foil or conductive rails/wires)
3p flexible pre-carrier (e.g. flexible pre-foil or conductive pre-rails/pre-wires)
31 conductive rails as the carrier or wiring within the flexible foil as the carrier
32 buffer area(s)
32p pre-buffer area(s)
321 (first) roof section of a buffer area shaped as a gable roof
322 (second) roof section of a buffer area shaped as a gable roof
323 roof ridge, where both roof sections meet
33 one edge of the flexible carrier (compressed side)
34 opposite edge of the flexible carrier (expanded side)
35 area of the flexible carrier between the buffer areas
10 automotive light unit
100 embossing tool
110 male embossing sub-tool
120 female embossing sub-tool
130 embossing surface of the male sub-tool
131 positive shape adapted to the demanded shape of the buffer area
140 embossing surface of the female sub-tool
141 negative shape adapted to the demanded shape of the buffer area
150 pair of positive and negative shapes of the embossing surfaces
160 recess of male or female sub-tool to receive the solid state lighting unit attached to the flexible pre-carrier
200 method to manufacture a light strip
210 providing a flexible pre-carrier
220 providing an embossing tool for embossing the flexible pre-carrier
230 inserting the pre-buffer areas of the flexible carrier into the embossing tool
240 transferring the pre-buffer area into the demanded shape of the buffer area
250 repeating the previous inserting and transferring steps
260 attaching the solid state lighting units to the embossed flexible carrier
BA bending axis
C compressed buffer area, compression
D distance between adjacent solid state lighting units
DW diameter of cylindrical wheels as male and female sub-tools
E expanded buffer area, expansibility
H maximum height of the buckling area
L length of the light strip
LBA local bending angle of the light strip
RA roof angle between both roof sections of the buffer area as a gable roof
W3 width of the flexible carrier

1. A flexible light strip comprising,
multiple solid state lighting units; and
a flexible carrier that comprises conductive rails attached and electrically coupled to the multiple solid state lighting units and multiple buffer areas between adjacent solid state lighting units of the multiple solid state lighting units, each of the multiple buffer areas extending along a width of the flexible carrier from one edge to an opposite edge of the flexible carrier and adapted to be compressed and expanded.

2. The light strip as claimed in claim 1, wherein each of the multiple solid state lighting units is adjacent at least one of the buffer areas along a length of the light strip.

3. The light strip as claimed in claim 1, wherein each of the multiple buffer areas is shaped as a buckling area.

4. The light strip as claimed in claim 3, wherein a maximum height of each of the multiple buffer areas above an area of the flexible carrier between adjacent buffer areas of the multiple buffer areas defines a maximum local bending angle for the light strip relative to a linear shape of the light strip when non-bended.

5. The light strip as claimed in claim 3, wherein each of the multiple buffer areas is shaped as a gable roof comprising two roof sections sloping in opposite directions and located such that the highest edges meet to form a roof ridge.

6. The light strip as claimed in claim 1, wherein at least the multiple buffer areas are made of a ductile material.

7. (canceled)

8. An embossing tool comprising:
at least one male sub-tool; and
at least one female sub-tool, each of the at least one male sub-tool and the at least one female sub-tool comprising embossing surfaces facing towards each other, the embossing surfaces comprising at least one positive and one corresponding negative shape adapted to a demanded shape of a buffer area of a light strip that comprises multiple solid state lighting units, a flexible carrier for the multiple solid state lighting units and buffer areas within the flexible carrier between adjacent solid state lighting units of the multiple solid state lighting units and adapted to be compressed and expanded on demand.

9. The embossing tool as claimed in claim 8, wherein the at least one male and female sub-tools are shaped as rotatable cylindrical wheels with lateral surfaces as the embossing surfaces comprising multiple positive and corresponding negative shapes.

10. The embossing tool as claimed in claim 9, wherein diameters of the rotatable cylindrical wheels are adapted to provide releasing of a received pair of the positive and corresponding negative shapes simultaneously to receive a following pair of the positive and negative shapes in order to continuously feed the flexible carrier through the embossing tool.

11. A method (200) of manufacturing a light strip comprising multiple solid state lighting units, a flexible carrier for the solid state lighting units and buffer areas between adjacent solid state lighting units, the method comprising:
providing a flexible pre-carrier that comprises a wiring and multiple flat pre-buffer areas along the flexible pre-carrier, separated from each other, and extending along a width of the flexible pre-carrier from one edge to an opposite edge of the flexible pre-carrier;
providing an embossing tool for an embossing process, the embossing tool comprising a male sub-tool and a female sub-tool each comprising embossing surfaces facing towards each other, the embossing surfaces comprising at least one positive and one corresponding negative shape adapted to a demanded shape of the buffer area of the light strip;
inserting at least the pre-buffer areas of the flexible pre-carrier into the embossing tool between the embossing surfaces;
transferring the flat pre-buffer area into the demanded shape of the buffer area by the positive and corresponding negative shapes; and
repeating the inserting and transferring for following non-treated pre-buffer areas of the flexible pre-carrier until all demanded buffer areas are shaped by the embossing process to be able to be compressed and expanded on demand.

12. The method as claimed in claim 11, further comprising attaching the solid state lighting units to the embossed flexible carrier.

13. The method as claimed in claim 11, wherein the flexible pre-carrier already carries one or more solid state lighting units between adjacent pre-buffer areas of the flexible pre-carrier before inserting the pre-buffer areas into the embossing tool.

14. The method as claimed in claim 11, wherein the male and female sub-tools are shaped as cylindrical wheels with lateral surfaces as the embossing surfaces comprising multiple positive and corresponding negative shapes located onto the embossing surfaces in order to receive each other during rotating the cylindrical wheels.

15. The light strip as claimed in claim 5, wherein a roof angle at the roof ridge is 90 degrees in a non-bended state of the light strip along a length of the light strip.

16. The embossing tool as claimed in claim 9, wherein the multiple positive and corresponding negative shapes are located on the cylindrical wheels such that they receive each other during rotation of the rotatable cylindrical wheels.

17. The method as claimed in claim 13, wherein the embossing surface of the male or female sub-tool comprises a recess suitable to receive the attached solid state lighting unit during embossing the pre-buffer areas.

18. The method as claimed in claim 13, wherein the inserting and transferring are executed by simultaneously rotating the cylindrical wheels with the flexible pre-carrier inserted between the cylindrical wheels.

19. The light strip as claimed in claim 1, wherein the conductive rails comprise two conductive rails.

20. The light strip as claimed in claim 19, wherein one of the two conductive rails defines the one edge of the flexible carrier and the other one of the two conductive rails defines opposite edge of the flexible carrier.

21. The light strip as claimed in claim 19, wherein the two conductive rails are configured for coupling to receive a drive current for the multiple solid state lighting units.
